(19) United States
(12) Patent Application Publication
(10) Pub. No.: US 2003/0054656 A1
(43) Pub. Date: Mar. 20, 2003

(54) Method for manufacturing semiconductor device including two-step ashing process of N2 plasma gas and N2/H2 plasma gas

(75) Inventor: Eiichi Soda, Tokyo (JP)

Correspondence Address: McGinn & Gibb, PLLC, Suite 200, 8321 Old Courthouse Road, Vienna, VA, 22182-3817, US

(73) Assignee: NEC Corporation, Tokyo (JP)

(21) Appl. No.: 10/237,053

(22) Filed: Sep. 9, 2002

(30) Foreign Application Priority Data
Sep. 19, 2001 (JP) 2001-284373

(51) Int. Cl. H01L 21/302; H01L 21/461

(52) U.S. Cl. 438/710; 438/723

(57) ABSTRACT

In a method for manufacturing a semiconductor device, a photoresist pattern layer is formed on an interlayer insulating layer made of inorganic material including CH₃-groups and/or H-groups. Then, the interlayer insulating layer is etched by using the photoresist pattern layer as a mask. Finally, a two-step ashing process is performed upon the photoresist pattern layer while the interlayer insulating layer is exposed. The two-step ashing process includes a first step using N₂ plasma gas and a second step using N₂/H₂ plasma gas after the first step.

### BACKGROUND OF THE INVENTION

1. Field of the Invention

The present invention relates to a method for manufacturing a semiconductor device, and more particularly, to a process for ashing a photoresist layer using plasma gas.

2. Description of the Related Art

Generally, in a method for manufacturing a semiconductor device, a photoresist pattern layer is formed on an interlayer insulating layer in a photolithography process, and then, the interlayer insulating layer is etched by using the photoresist pattern layer as a mask in an etching process. Then, the potoresist pattern layer is removed by using O₂ plasma gas in an ashing process.

On the other hand, as semiconductor devices have been more-fined, the capacitance of interlayer insulating material has been increased to decrease the propagation speed of signals. In order to decrease the capacitance of interlayer insulating material, use is made of inorganic material including CH₃-groups or H-groups as an interlayer insulating layer having a low dielectric constant.

However, an ashing process using O₂ plasma gas is carried out while a part of the inorganic material including CH₃-groups or H-groups is exposed, an overhang shape is generated in the inorganic material including CH₃-groups or H-groups. Even if an ashing process using N₂/H₂ plasma gas is carried out while a part of the inorganic material including OH₃-groups or H-groups is exposed, an overhang shape is still generated in the inorganic material including CH₃-groups or H-groups. This will be explained later in detail.

Note that an ashing process using N₂/H₂ plasma gas is disclosed in JP-A-10-209118 where use is made of organic material as an interlayer insulating layer.

### SUMMARY OF THE INVENTION

It is an object of the present invention to provide a method for manufacturing a semiconductor device including an ashing process capable of suppressing the generation of overhang shape in an interlayer insulating layer made of inorganic material including CH₃-groups and/or H-groups.

According to the present invention, in a method for manufacturing a semiconductor device, a photoresist pattern layer is formed on an interlayer insulating layer made of inorganic material including CH₃-groups and/or H-groups. Then, the interlayer insulating layer is etched by using the photoresist pattern layer as a mask. Finally, a two-step ashing process is performed upon the photoresist pattern layer while the interlayer insulating layer is exposed. The two-step ashing process includes a first step using N₂plasma gas and a second step N₂/H₂ plasma gas after the first step.

The inorganic material is hardly etched by the above-mentioned two-step ashing process.

### BRIEF DESCRIPTION OF THE DRAWINGS

The present invention will be more clearly understood from the description set forth below, as compared with the prior art, with reference to the accompanying drawings, wherein:

FIG. 1 is a cross-sectional view illustrating a conventional asher apparatus;

FIGS. 2A, 2B and 2C are diagrams showing chemical structures of inorganic material including CH₃-group or H-groups;

FIGS. 3A through 3K are cross-sectional views for explaining a prior art method for manufacturing a semiconductor device;

FIGS. 4A, 4B and 4C are diagrams showing chemical structures of inorganic material of FIGS. 2A, 2B and 2C, respectively, where CH₃-groups or H-groups are eliminated;

FIGS. 5A through 5M are cross-sectional views for explaining a first embodiment of the method for manufacturing a semiconductor device according to the present invention;

FIG. 6A, 6B and 6C are diagrams showing chemical structures of inorganic material of FIGS. 2A, 2B and 2C, respectively, where CH₃-groups or H-groups are changed to CN-groups or N-groups;

FIGS. 7A through 7L are cross-sectional views for explaining a second embodiment of the method for manufacturing a semiconductor device according to the present invention;

FIGS. 8A through 8K are cross-sectional views for explaining a third embodiment of the method for manufacturing a semiconductor device according to the present invention;

FIG. 9A is a cross-sectional view of a sample for explaining the effect of the present invention; and

FIG. 9B is a graph showing the effect of the present invention.

### DESCRIPTION OF THE PREFERRED EMBODIMENTS

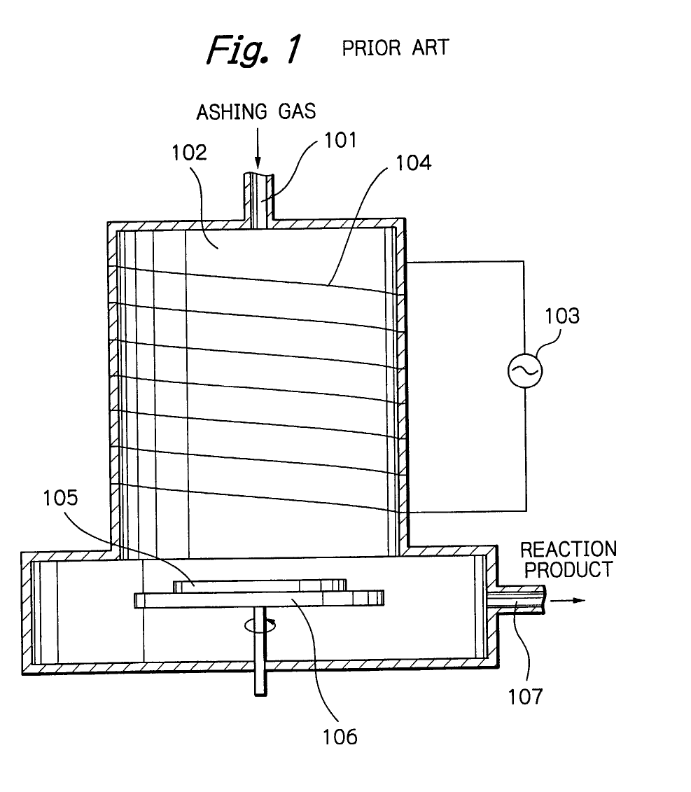

Before the description of the preferred embodiments, a prior art method for manufacturing a semiconductor device will be explained with reference to FIGS. 1, 2A, 2B, 2C, 3A through 3K, 4A, 4B and 4C.

In FIG. 1, which is a cross-sectional view illustrating an asher apparatus, the asher apparatus is of an inductively-coupled plasma (ICP) type where ashing gas is introduced from a gas inlet 101 into vacuum chamber 102. When a high frequency power is supplied from a radio frequency (RF) source 103 to a winding 104 wound on the vacuum chamber 102, inductively-coupled plasma gas is generated within the vacuum chamber 102. The plasma gas is move down, so that a wafer 105 fixed to a stage 106 is exposed to the plasma gas, thus performing an ashing operation upon the wafer 105. Then, reaction product is exhausted from a gas outlet 107. The asher apparatus can be of a surface wave plasma (SWP) type. Also, an etcher apparatus of a two-wave, reactive ion etching (RIE) type or an ICP type can be used as an asher apparatus. Further, a bias power can be applied to the asher apparatus.

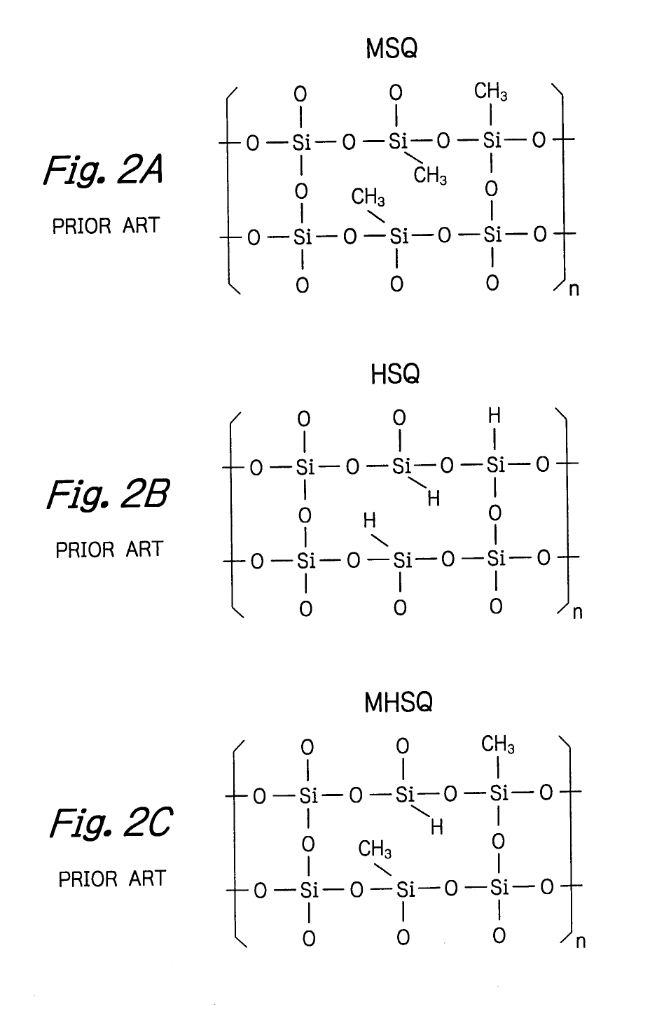

Examples of inorganic material including CH₃-groups or H-groups are shown in FIGS. 2A, 2B and 2C, which show methyl silsesquioxane (MSQ), hydrogen silsesquioxane (HSQ) and methyl hydrogen silsequioxane (MHSQ), respectively.

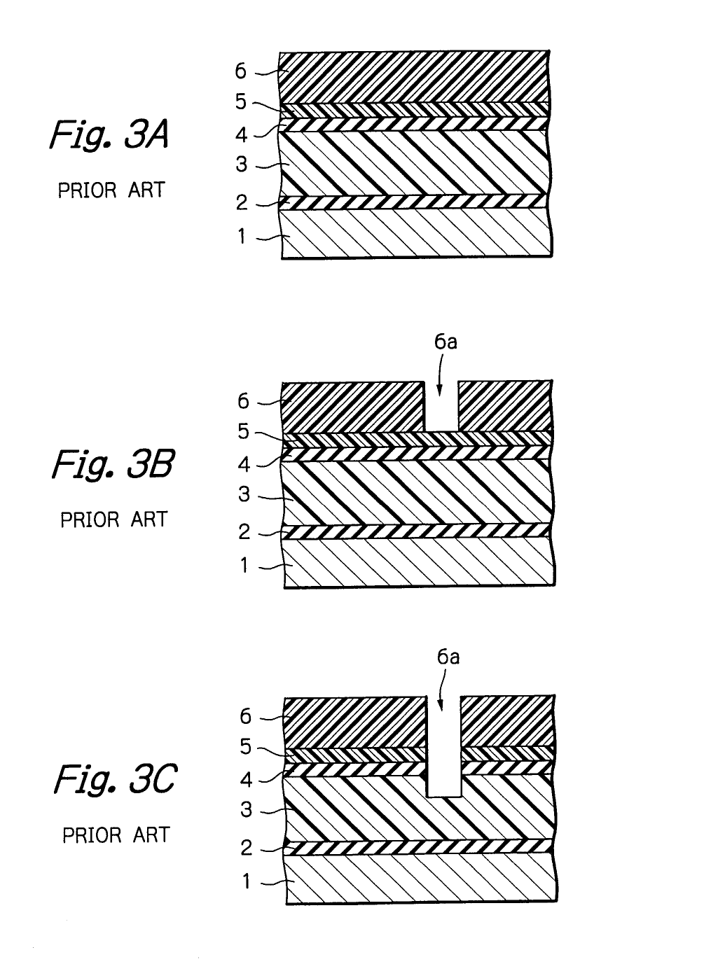

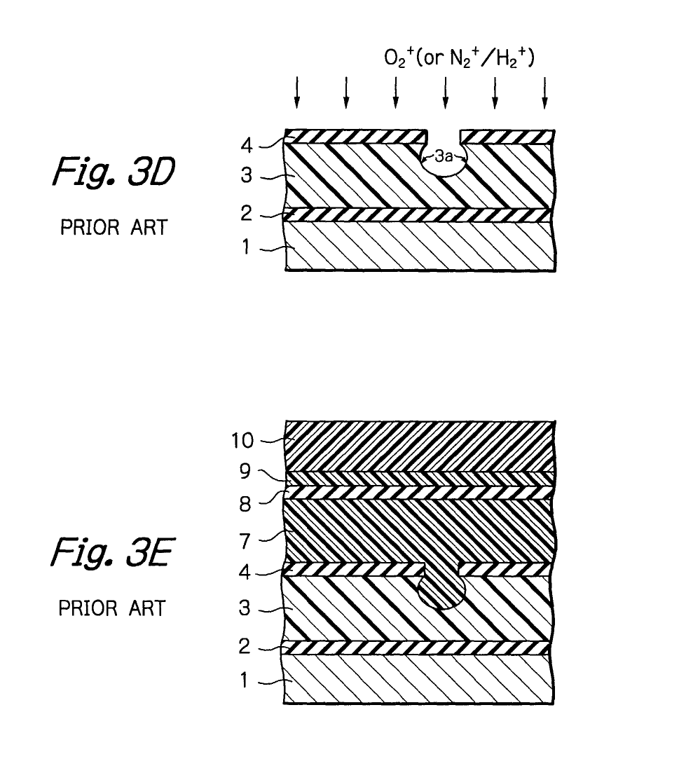

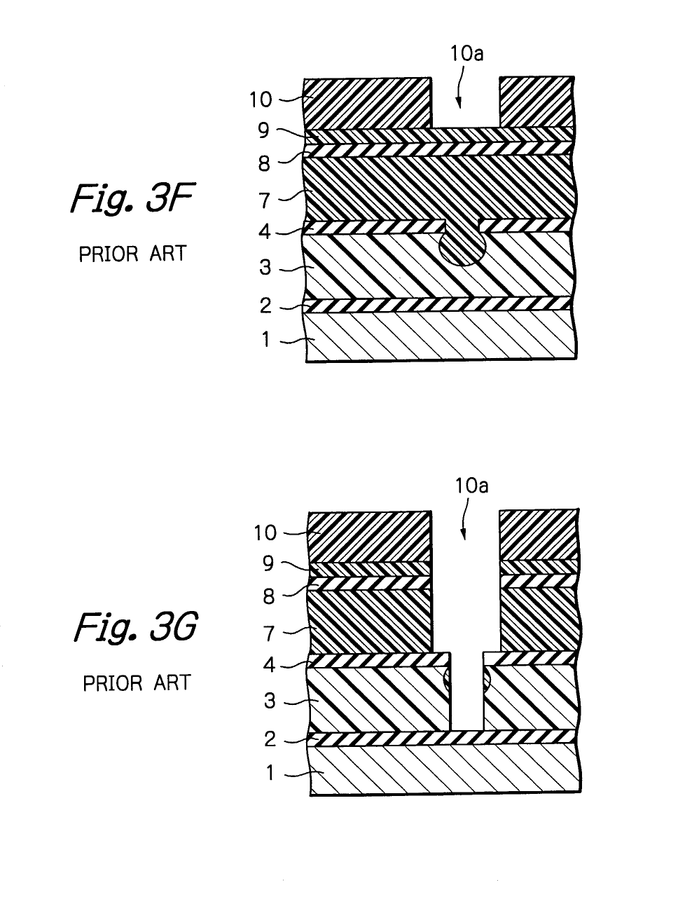

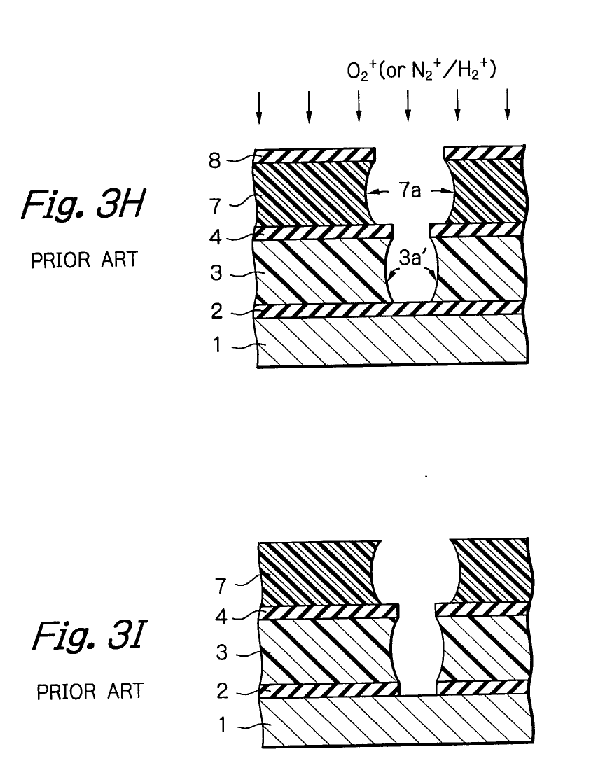

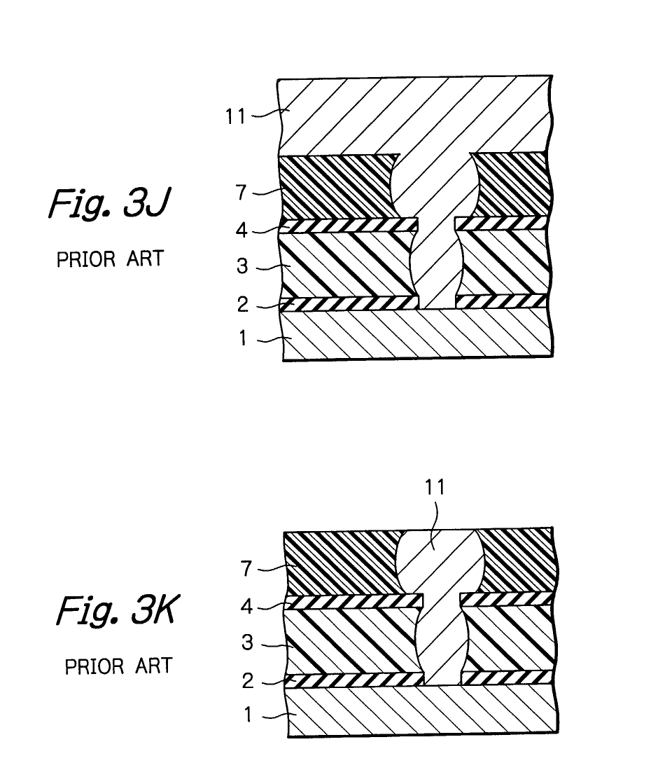

A prior art method for manufacturing a semiconductor device including a dual-damascene structure using a middle first method will be explained next with reference to FIGS. 3A through 3K.

First, referring to FIG. 3A, a lower wiring layer 1 made of copper is formed on an insulating substrate (not shown). Then, an about 50 nm thick via stopper 2 made SiC, an about 300 nm thick interlayer insulating layer 3 made of MSQ, HSQ or MHSQ, and an about 50 nm thick groove stopper 4 made of SiC are sequentially deposited on the lower wiring layer 1. Then, an anti-reflective coating layer 5 and a KrF photoresist layer 6 are sequentially coated thereon.

Next, referring to FIG. 3B, a via hole 6a having an about 0.15 μm diameter is formed in the KrF photoresist layer 6.

Next, referring to FIG. 3C, the anti-reflective coating layer 5 and the groove stopper 4 are etched by a dry etching process using the KrF photoresist layer 6 as a mask. For example, this dry etching process is carried out by a two-wave, RIE etcher apparatus using CF₄ plasma gas, Ar plasma gas or O₂ plasma gas. In this case, a part of the interlayer insulating layer 3 is also etched.

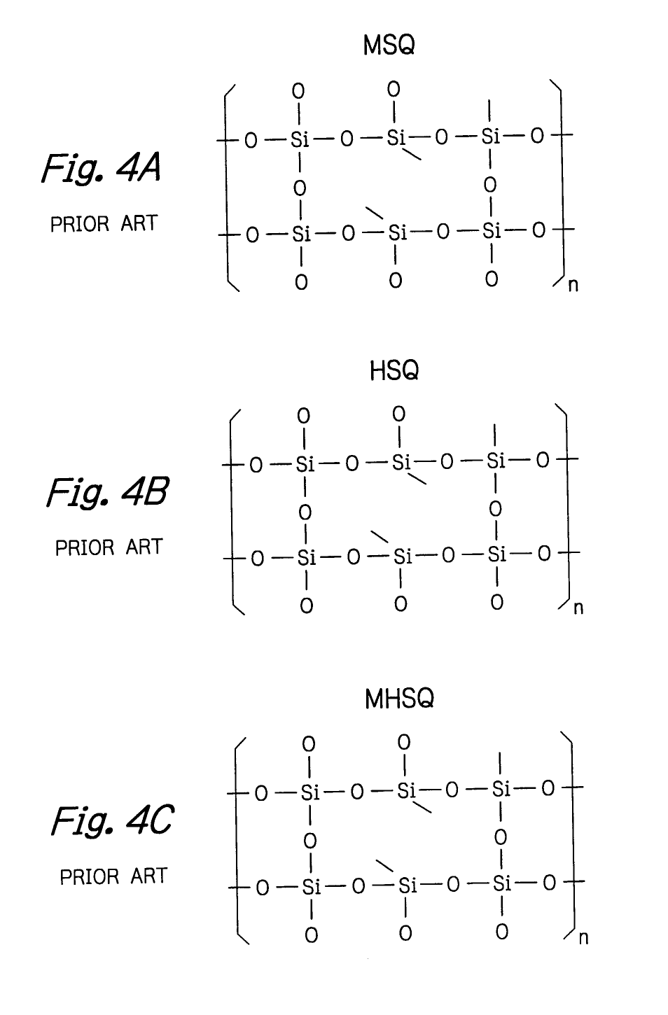

Next, referring to FIG. 3D, the KrF photoresist layer 6 and the anti-reflective coating layer 5 are ashed in the asher apparatus of FIG. 1 by using O₂ plasma gas or N₂/H₂ plasma gas. In this case, CH₃-groups or H-groups are eliminated from MSQ, HSQ or MHSQ as shown in FIGS. 4A, 4B and 4C. As a result, a small overhang shape is generated in the interlayer insulating layer 3 as indicated by 3a in FIG. 3D. Then, an organic separating process is carried out.

Next, referring to FIG. 3E, an about 300 nm thick interlayer insulating layer 7 made of MSQ, HSQ or MHSQ, and an about 50 nm thick hard mask 8 made of SiC are sequentially deposited on the groove stopper 4. Then, an anti-reflective coating layer 9 and a KrF photoresist layer 10 are sequentially coated thereon.

Next, referring to FIG. 3F, a groove 10a having an about 0.18 μm width is formed in the KrF photoresist layer 10. Note that a spacing between the groove 10a and its adjacent groove (not shown) is about 0.18 μm.

Next, referring to FIG. 3G, the anti-reflective coating layer 9, the hard mask 8 and the interlayer insulating layers 7 and 3 are etched by a dry etching process using the KrF photoresist layer 10 as a mask. For example, this dry etching process is carried out by a two-wave, RIE etcher apparatus using CF₄ plasma gas, Ar plasma gas or O₂ plasma gas for the anti-reflective coating layer 9 and the hard mask 8, and C₄F₈ plasma gas, Ar plasma gas or N₂ plasma gas for the interlayer insulating layers 7 and 3.

Next, referring to FIG. 3H, the KrF photoresist layer 10 and the anti-reflective coating layer 9 are ashed in the asher apparatus of FIG. 1 by using O₂ plasma gas or N₂/H₂ plasma gas. In this case, CH₃-groups or H-groups are eliminated from MSQ, HSQ or MHSQ as shown in FIGS. 4A, 4B and 4C. As a result, large overhang shapes are generated in the interlayers insulating layers 7 and 3 as indicated by 7a and 3a′ in FIG. 3H. Then, an organic separating process is carried out.

Next, referring to FIG. 3I, the hard mask 8 and the exposed portion of the via stopper 2 are etched by a two-wave, type RIE process using CF₄ plasma gas, Ar plasma gas or O₂ plasma gas.

Next, referring to FIG. 3J, an upper wiring layer 11 made of copper is formed on the entire surface.

Finally, referring to FIG. 3K, the upper wiring layer 11 is etched back by a two-wave, RIE process, so that the upper wiring layer 11 is left within the groove in the interlayer insulating layer 7 and is electrically connected to the lower wiring layer 1 by the via structure in the interlayer insulating layer 3.

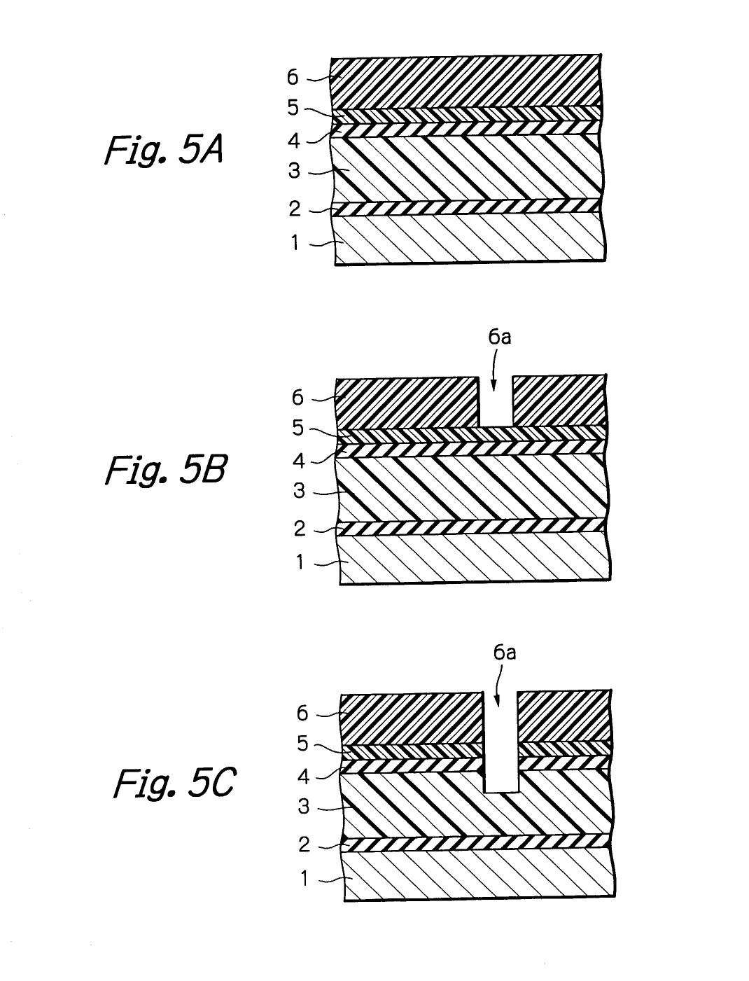

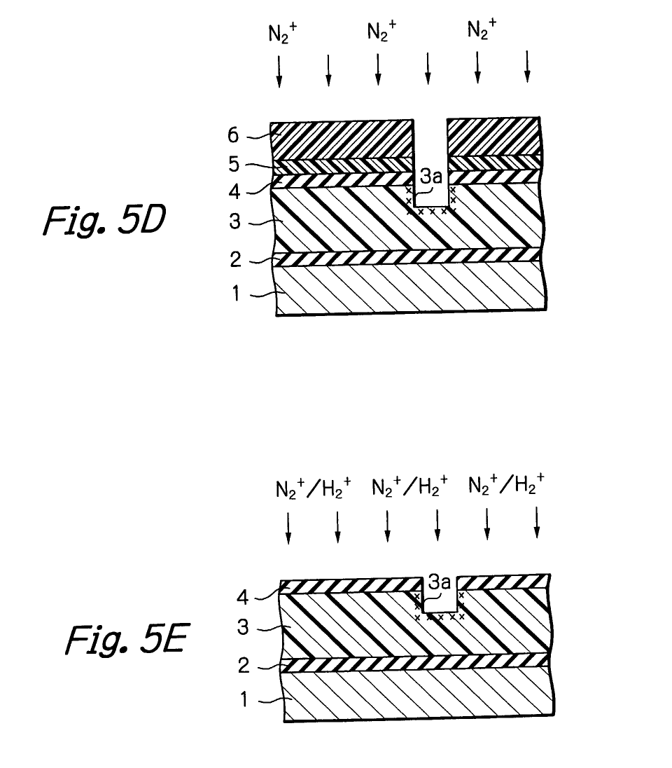

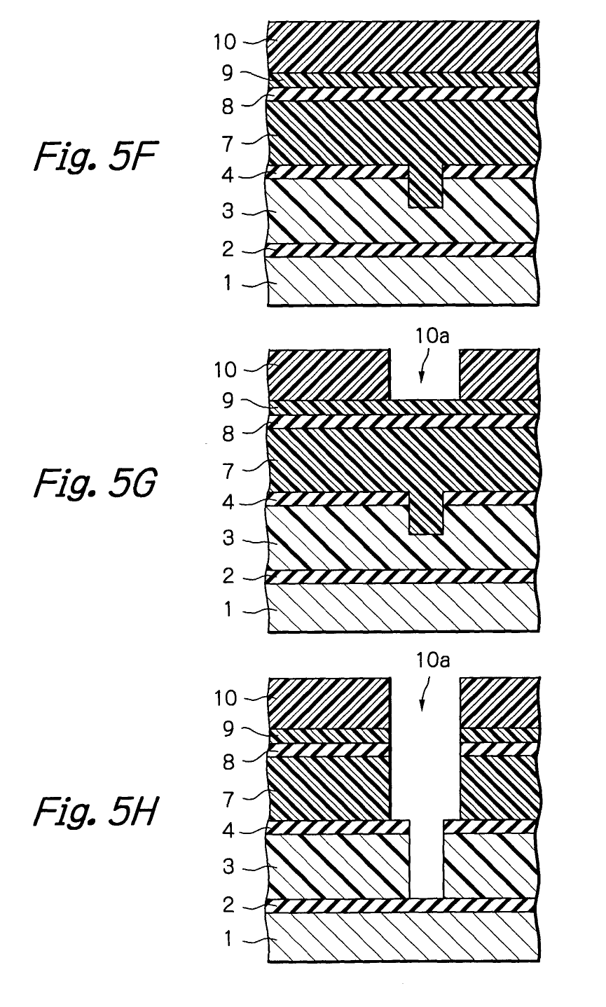

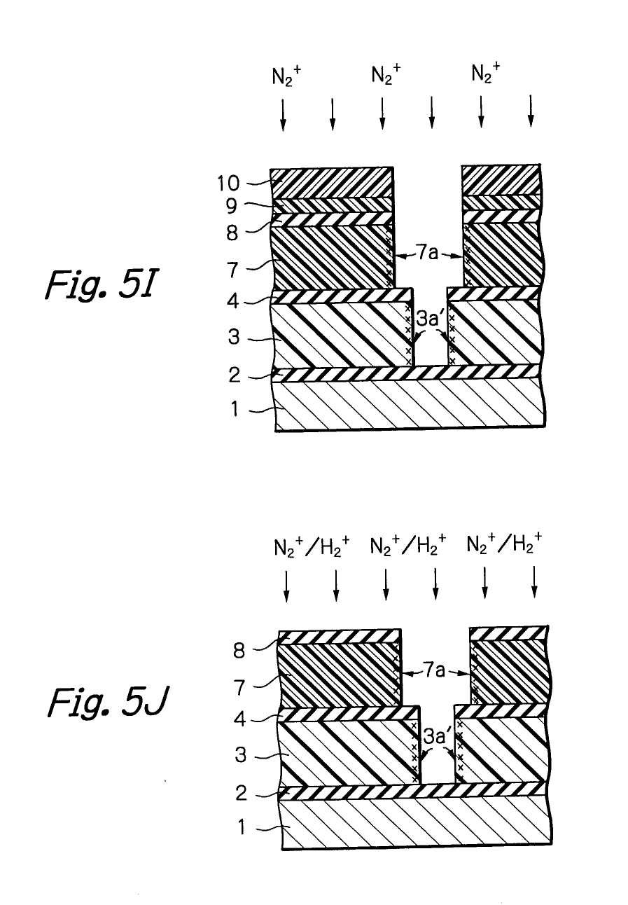

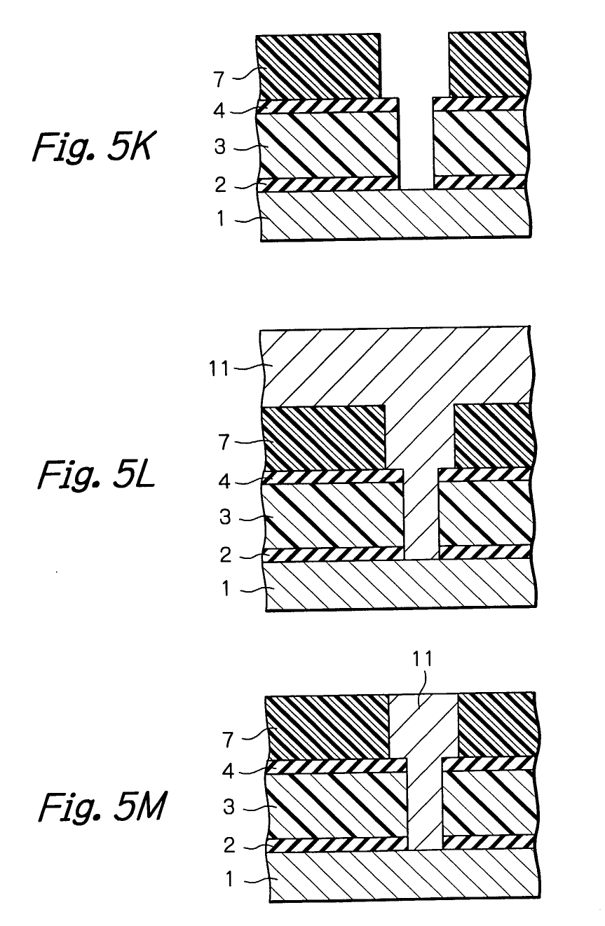

A first embodiment of the method for manufacturing a semiconductor device including a dual-damascene structure will be explained next with reference to FIGS. 5A through 5M. In this case, the dual-damascene structure uses a middle first method.

First, referring to FIG. 5A, in the same way as in FIG. 3A, a lower wiring layer 1 made of copper is formed on an insulating substrate (not shown). Then, an about 50 nm thick via stopper 2 made SiC, an about 300 nm thick interlayer insulating layer 3 made of MSQ, HSQ or MHSQ, and an about 50 nm thick groove stopper 4 made of SiC are sequentially deposited on the lower wiring layer 1. Then, an anti-reflective coating layer 5 and a KrF photoresist layer 6 are sequentially coated thereon.

Next, referring to FIG. 5B, in the same way as in FIG. 3B, a via hole 6a having an about 0.15 μm diameter is formed in the KrF photoresist layer 6.

Next, referring to FIG. 5C, in the same way as in FIG. 3C, the anti-reflective coating layer 5 and the groove stopper 4 are etched by a dry etching process using the KrF photoresist layer 6 as a mask. For example, this dry etching process is carried out by a two-wave, RIE etcher apparatus using CF₄ plasma gas, Ar plasma gas or O₂ plasma gas. In this case, a part of the interlayer insulating layer 3 is also etched.

Next, referring to FIGS. 5D and 5E, the KrF photoresist layer 6 and the anti-reflective coating layer 5 are ashed in the asher apparatus of FIG. 1 by using two steps of ashing process.

As illustrated in FIG. 5D, the first ashing step is carried out for about 60 sec under the following conditions:

the pressure in the chamber 102 is about 1.33 Pa (10 mTorr) to 13.3 Pa (100 mTorr);

the power of the RF source 103 is 2500 W;

the bias power is 300 W;

the N₂ gas is 500 sccm; and

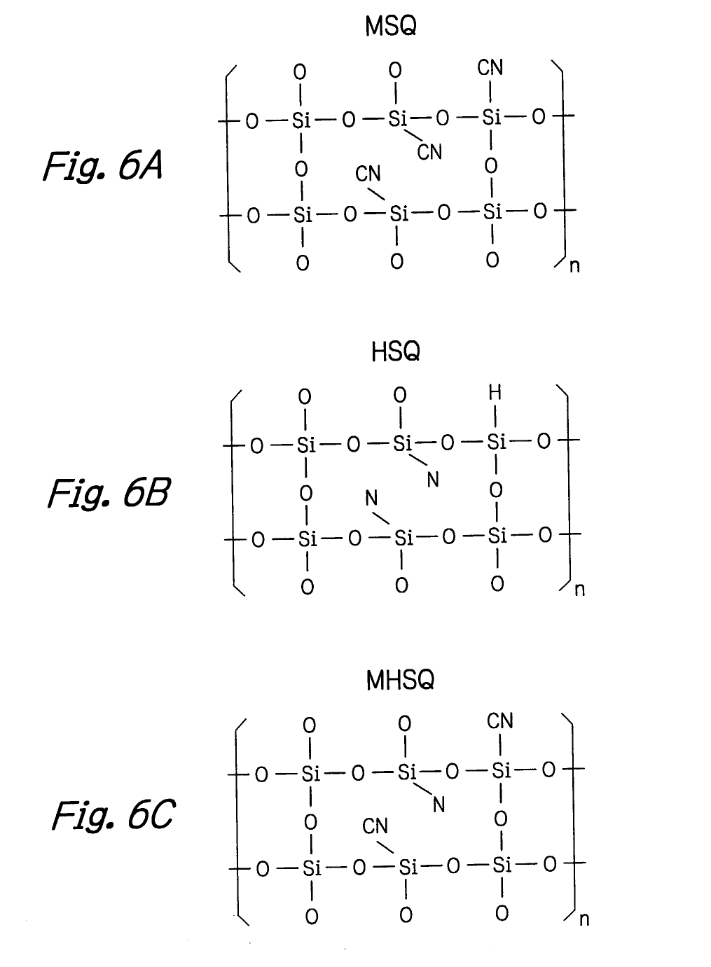

the temperature of the substrate (wafer) is about 0° C. to 80° C., preferably 20° C. As a result, at a sidewall portion of the interlayer insulating layer 3, CH₃-groups or H-groups of MSQ, HSQ or MHSQ are changed to CN-groups or N-groups as illustrated in FIG. 6A, 6B or 6C, to form a protection layer 3a as indicated by X in FIG. 5D.

As illustrated in FIG. 5E, the second ashing step is carried out for about 200 sec under the following conditions:

the pressure in the chamber 102 is about 1.33 Pa (10 mTorr) to 13.3 Pa (100 mTorr);

the power of the RF source 103 is 2500 W;

the bias power is 300 W;

the N₂ gas is 450 sccm;

the H₂ gas is 50 sccm; and

the temperature of the substrate (wafer) is about 0° C. to 80° C., preferably 20° C. In this case, the protection layer 3a prevents the interlayer insulating layer 3 from being ashed by N₂ plasma gas and H₂ plasma gas. Thus, no overhang shape is generated in the interlayer insulating layer 3.

Then, an organic separating process is carried out.

Next, referring to FIG. 5F, in the same way as in FIG. 3E, an about 300 nm thick interlayer insulating layer 7 made of MSQ, HSQ or MHSQ, and an about 50 nm thick hard mask 8 made of SiC are sequentially deposited on the groove stopper 4. Then, an anti-reflective coating layer 9 and a KrF photoresist layer 10 are sequentially coated thereon.

Next, referring to FIG. 5G, in the same way as in FIG. 3F, a groove 10a having an about 0.18 μm width is formed in the KrF photoresist layer 10. Note that a spacing between the groove 10a and its adjacent groove (not shown) is about 0.18 μm.

Next, referring to FIG. 5H, in the same way as in FIG. 3G, the anti-reflective coating layer 9, the hard mask 8 and the interlayer insulating layers 7 and 3 etched by the dry etching process using the KrF photoresist layer 10 as a mask. For example, this dry etching process is carried out by a two-wave, RIE etcher apparatus using CF₄ plasma gas, Ar plasma gas or O₂ plasma gas for the anti-reflective coating layer 9 and the hard mask 8, and C₄F₈ plasma gas, Ar plasma gas or N₂ plasma gas for the interlayer insulating layers 7 and 3.

Next, referring to FIGS. 5I and 5J, the KrF photoresist layer 10 and the anti-reflective coating layer 9 are ashed in the asher apparatus of FIG. 1 by using two steps of ashing process in the same way as in FIGS. 5D and 5E. As a result, protection layers 7a and 3a′ are formed at sidewalls of the interlayer insulating layers 7 and 3 by the first ashing step, so that no overhang shape is generated in the interlayer insulating layers 7 and 3.

Then, an organic separating process is carried out.

Next, referring to FIG. 5K, in the same way as in FIG. 31, the hard mask 8 and the exposed portion of the via stopper 2 are etched by a two-wave, type RIE process using CF₄ plasma gas, Ar plasma gas or O₂ plasma gas.

Next, referring to FIG. 5L, in the same way as in FIG. 3J, an upper wiring layer 11 made of copper is formed on the entire surface.

Finally, referring to FIG. 5M, in the same way as in FIG. 3K, the upper wiring layer 11 is etched back by a two-wave, RIE process, so that the upper wiring layer 11 is left within the groove in the interlayer insulating layer 7 and is electrically connected to the lower wiring layer 1 by the via structure in the interlayer insulating layer 3.

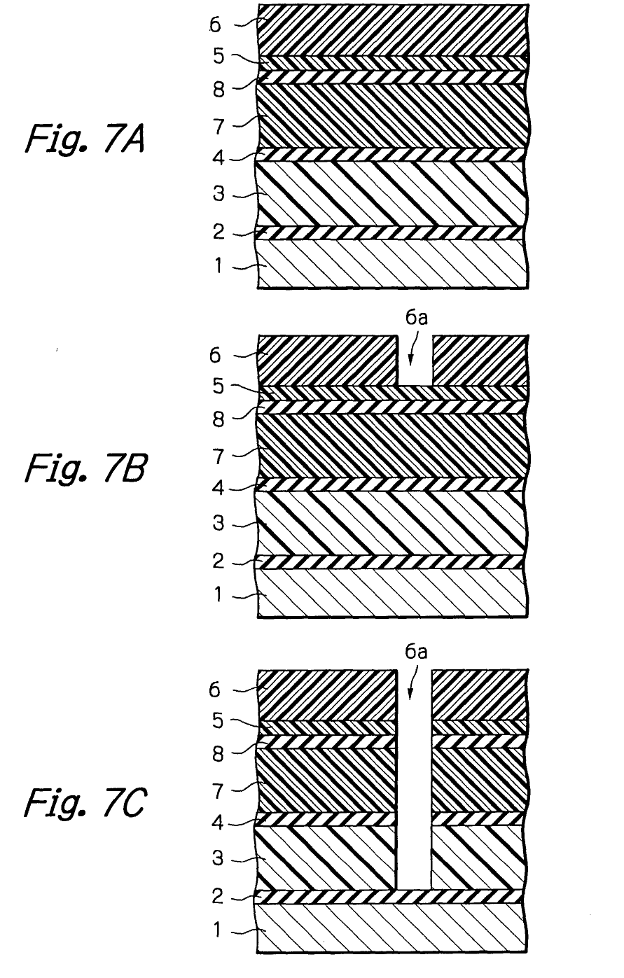

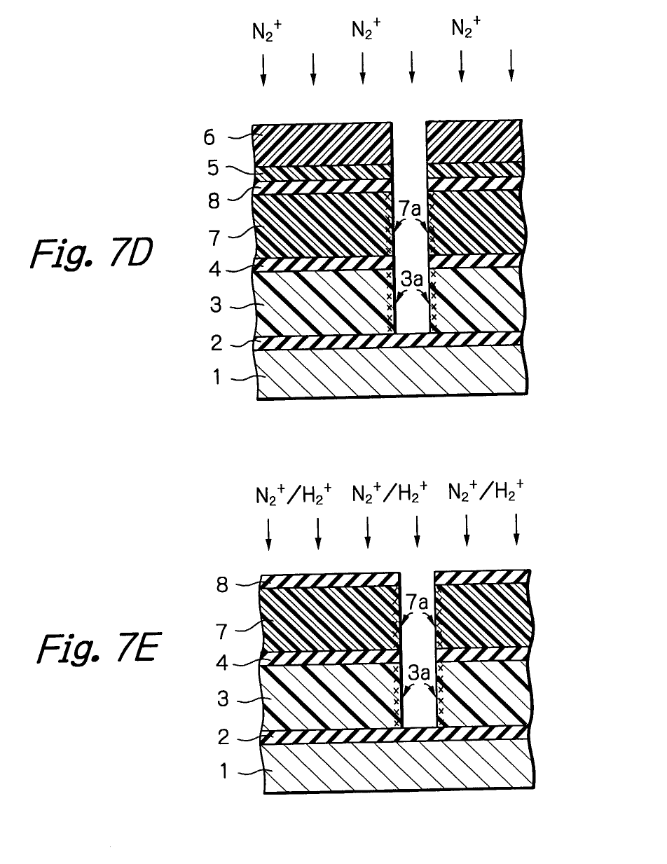

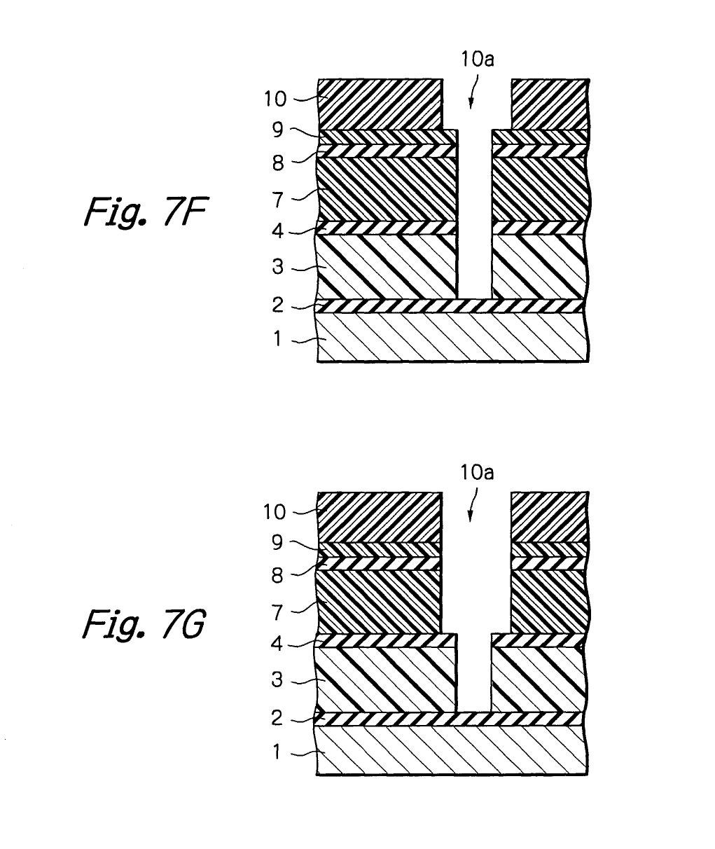

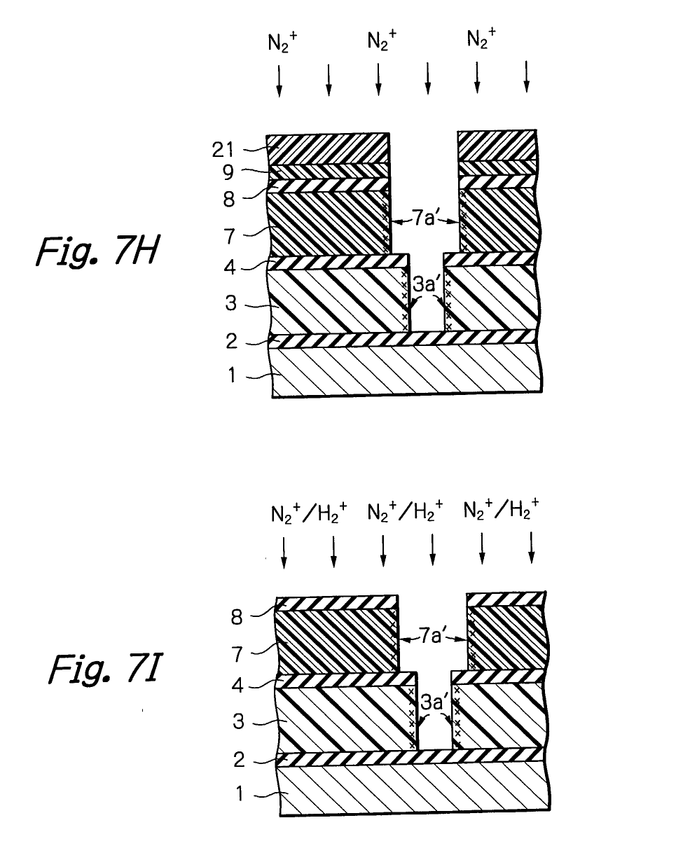

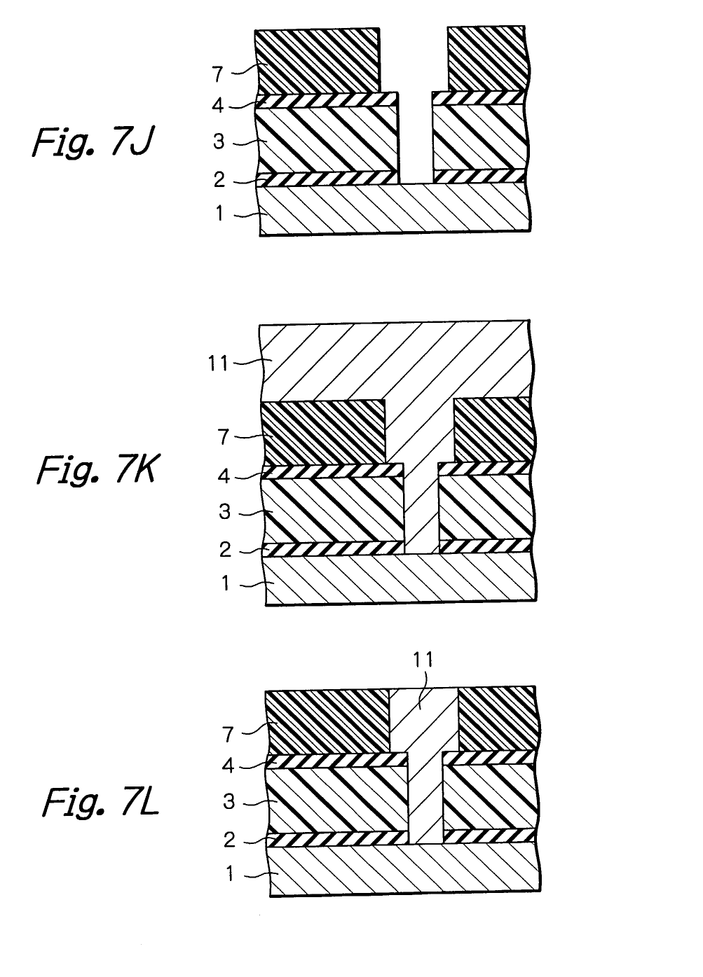

A second embodiment of the method for manufacturing a semiconductor device including a dual-damascene structure will be explained next with reference to FIGS. 7A through 7L. In this case, the dual-damascene structure uses a via first method.

First, referring to FIG. 7A, a lower wiring layer 1 made of copper is formed on an insulating substrate (not shown). Then, an about 50 nm thick via stopper 2 made SiC, an about 300 nm thick interlayer insulating layer 3 made of MSQ, HSQ or MHSQ, and an about 50 nm thick groove stopper 4 made of SiC an about 300 nm thick interlayer insulating layer 7 made of MSQ, HSQ or MHSQ and an abut 50 nm thick hard mask 8 made of SiC are sequentially deposited on the lower wiring layer 1. Then, an anti-reflective coating layer 5 and a KrF photoresist layer 6 are sequentially coated thereon.

Next, referring to FIG. 7B, in the same way as in FIG. 3B, a via hole 6a having an about 0.15 μm diameter is formed in the KrF photoresist layer 6.

Next, referring to FIG. 7C, the anti-reflective coating layer 5, the hard mask 8, the interlayer insulating layer 7, the groove stopper 4 and the interlayer insulating layer 3 are etched by a dry etching process using the KrF photoresist layer 6 as a mask. For example, this dry etching process is carried out by a two-wave, RIE etcher apparatus using CF₄ plasma gas, Ar plasma gas or O₂ plasma gas for SiC and C₄F₈ plasma gas, Ar plasma gas or N₂ plasma gas for MSQ, HSQ or MHSQ.

Next, referring to FIG. 7D and 7E, in the same way as in FIG. 7D and 7E, the KrF photoresist layer 6 and the anti-reflective coating layer 5 are ashed in the asher apparatus of FIG. 1 by using two steps of ashing process.

That is, as illustrated in FIG. 7D, the first ashing step is carried out for about 60 sec under the following conditions:

the pressure in the chamber 102 is about 1.33 Pa (10 mTorr) to 13.3 Pa (100 mTorr);

the power of the RF source 103 is 2500 W;

the bias power is 300 W;

the N₂ gas is 500 sccm; and

the temperature of the substrate (wafer) is about 0° C. to 80° C., preferably 20° C. As a result, at sidewall portions of the interlayer insulating layers 7 and 3, CH₃-groups or H-groups of MSQ, HSQ or MHSQ are changed to CN-groups or N-groups as illustrated in FIG. 6A, 6B or 6C, to form protection layers 7a and 3a as indicated by X in FIG. 7D.

Also, as illustrated in FIG. 7E, the second ashing step is carried out for about 200 sec under the following conditions:

the pressure in the chamber 102 is about 1.33 Pa (10 mTorr) to 13.3 Pa (100 mTorr);

the power of the RF source 103 is 2500 W;

the bias power is 300 W;

the N₂ gas is 450 sccm;

the H₂ gas is 50 sccm; and

the temperature of the substrate (wafer) is about 0° C. to 80° C., preferably 20° C. In this case, the protection layers 7a and 3a prevent the interlayer insulating layers 7 and 3 from being ashed by N₂ plasma gas and H₂ plasma gas. Thus, no overhang shape is generated in the interlayer insulating layers 7 and 3.

Then, an organic separating process is carried out.

Next, referring to FIG. 7F, an anti-reflective coating layer 9 and a KrF photoresist layer 10 are sequentially coated on the entire surface. Then, a groove 10a having an about 0.18 μm width is formed in the KrF photoresist layer 10. Note that a spacing between the groove 10a and its adjacent groove (not shown) is about 0.18 μm.

Next, referring to FIG. 7G, the anti-reflective coating layer 9, the hard mask 8 and, the interlayer insulating layers 7 and 3 etched by the dry etching process using the KrF photoresist layer 10 as a mask. For example, this dry etching process is carried out by a two-wave, RIE etcher apparatus using CF₄ plasma gas, Ar plasma gas or O₂ plasma gas for the anti-reflective coating layer 9 and the hard mask 8, and C₄F₈ plasma gas, Ar plasma gas or N₂ plasma gas for the interlayer insulating layers 7 and 3.

Next, referring to FIGS. 5I and 5J, the KrF photoresist layer 10 and the anti-reflective coating layer 9 are ashed in the asher apparatus of FIG. 1 by using two steps of ashing process in the same way as in FIGS. 7D and 7E. As a result, protection layers 7′a and 3a′ are formed at sidewalls of the interlayer insulating layers 7 and 3 by the first ashing step, so that no overhang shape is generated in the interlayer insulating layers 7 and 3.

Then, an organic separating process is carried out.

Next, referring to FIG. 7J, in the same way as in FIG. 3I, the hard mask 8 and the exposed portion of the via stopper 2 are etched by a two-wave, type RIE process using CF₄ plasma gas, Ar plasma gas or O₂ plasma gas.

Next, referring to FIG. 7K, in the same way as in FIG. 3J, an upper wiring layer 11 made of copper is formed on the entire surface.

Finally, referring to FIG. 7L, in the same way as in FIG. 3K, the upper wiring layer 11 is etched back by a two-wave, RIE process, so that the upper wiring layer 11 is left within the groove in the interlayer insulating layer 7 and is electrically connected to the lower wiring layer 1 by the via structure in the interlayer insulating layer 3.

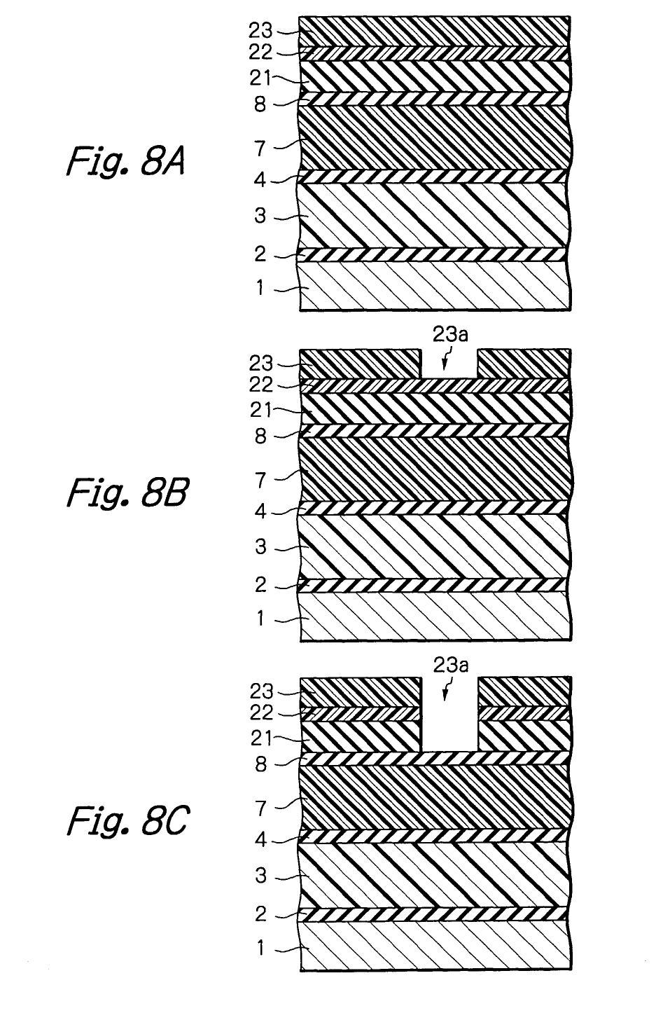

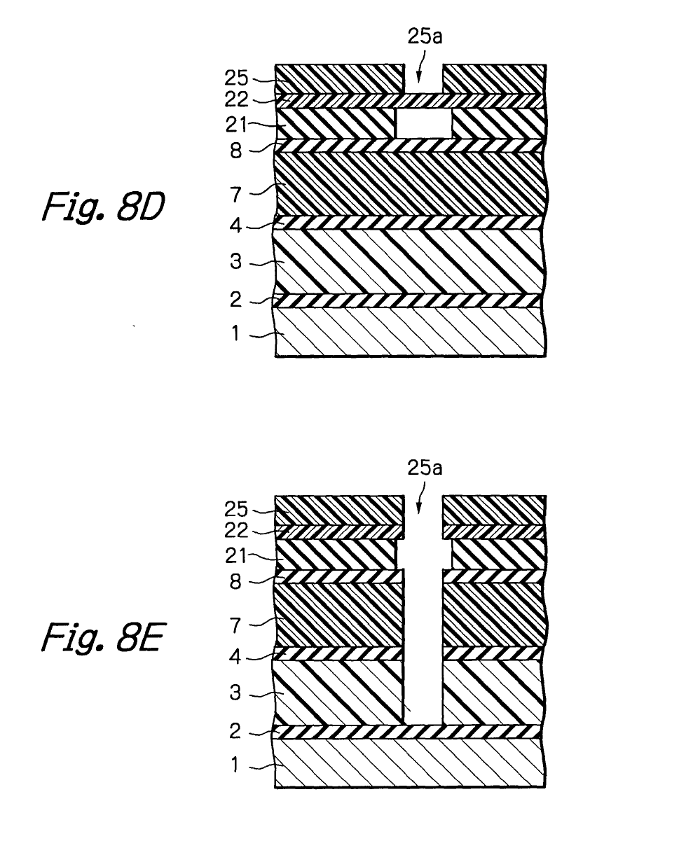

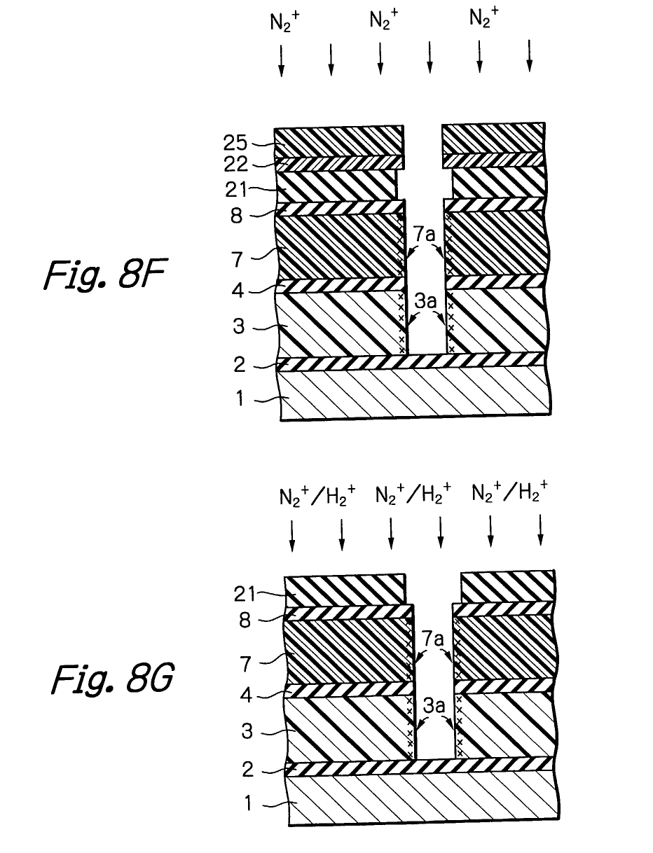

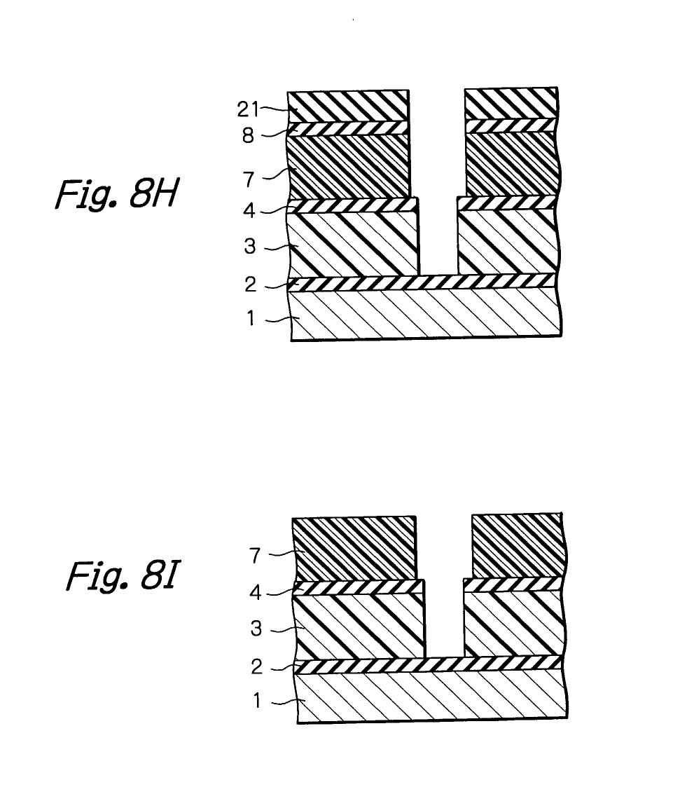

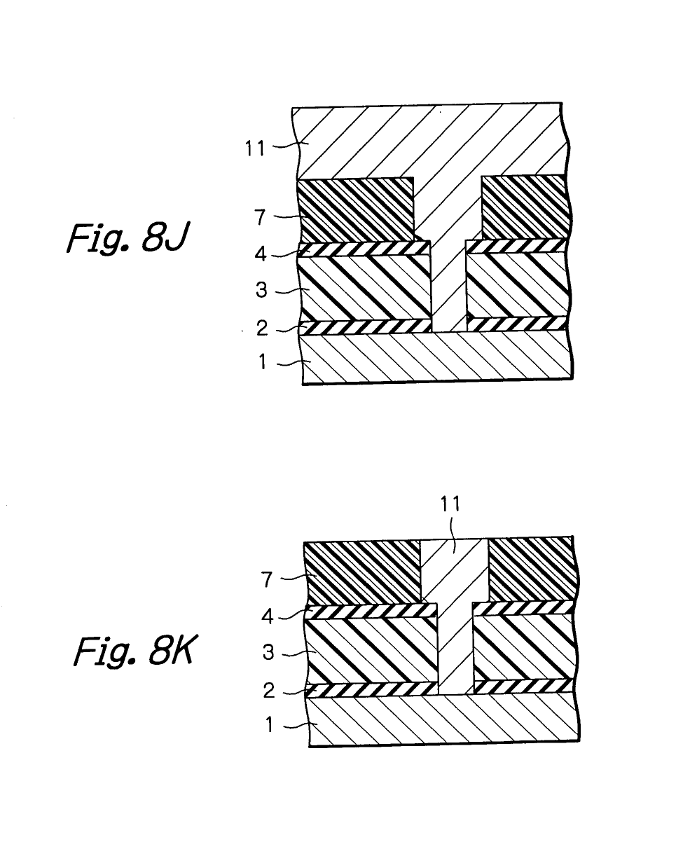

A third embodiment of the method for manufacturing a semiconductor device including a dual-damascene structure will be explained next with reference to FIGS. 8A through 8K. In this case, the dual-damascene structure uses a dual hard mask method.

First, referring to FIG. 8A, a lower wiring layer 1 made of copper is formed on an insulating substrate (not shown). Then, an about 50 nm thick via stopper 2 made SiC, an about 300 nm thick interlayer insulating layer 3 made of MSQ, HSQ or MHSQ, and an about 50 nm thick groove stopper 4 made of SiC an about 300 nm thick interlayer insulating layer 7 made of MSQ, HSQ or MHSQ, an abut 50 nm thick hard mask 8 made of SiC and an about 120 nm thick hard mask 21 made of SiN are sequentially deposited on the lower wiring layer 1. Then, an anti-reflective coating layer 22 and a KrF photoresist layer 23 are sequentially coated thereon.

Next, referring to FIG. 8B, a grove 23a having an about 0.18 μm width is formed in the KrF photoresist layer 6. Note that a spacing between the groove 23a and its adjacent groove (not shown) is 0.18 μm.

Next, referring to FIG. 8C, the hard mask 21 is etched by a dry etching process using the KrF photoresist layer 23 as a mask. Then, the KrF photoresist layer 23 and the anti-reflective coating layer 22 are ashed in the asher apparatus of FIG. 1 by the conventional ashing process using O₂ plasma gas or the like.

Next, referring to FIG. 8D, an anit-reflective coating layer 24 and a KrF photoresist layer 25 are sequentially coated, and a groove hole 25a having an about 0.15 μm diameter is formed in the KrF photoresist layer 25.

Next, referring to FIG. 8E, the anti-reflective layer 24, the hard mask 8, the interlayer insulating layer 7, the groove stopper 4, and the interlayer insulating layer 3 are etched by a dry etching process using the KrF photoresist layer 25 as a mask. For example, this dry etching process is carried out by a two-wave, RIE etcher apparatus using CF₄ plasmas gas, Ar plasma gas or O₂ plasma gas for the anti-reflective coating layer 24 and the hard mask 8 and the groove stopper 4 and C₄F₈ plasmas gas, Ar plasma gas or N₂ plasma gas for the interlayer insulating layers 7 and 3.

Next, referring to FIGS. 8F and 8G, in the same way as in FIGS. 5D and 5E, the KrF photoresist layer 25 and the anti-reflective layer 24 are ashed in the asher apparatus of FIG. 1 by using two steps of ashing process.

That is, as illustrated in FIG. 8F, the first ashing step is carried out for about 60 sec under the following conditions:

the pressure in the chamber 102 is about 1.33 Pa (10 mTorr) to 13.3 Pa (100 mTorr);

the power of the RF source 103 is 2500 W;

the bias power is 300 W;

the N₂ gas is 500 sccm; and

the temperature of the substrate (wafer) is about 0° C. to 80° C., preferably 20° C. As a result, at sidewall portions of the interlayer insulating layers 7 and 3, CH₃-groups or H-groups of MSQ, HSQ or MHSQ are changed to CN-groups or N-groups as illustrated in FIG. 6A, 6B or 6C, to form protection layers 7a and 3a as indicated by X in FIG. 8F.

Also, as illustrated in FIG. 8G, the second ashing step is carried out for about 200 sec under the following conditions:

the pressure in the chamber 102 is about 1.33 Pa (10 mTorr) to 13.3 Pa (100 mTorr);

the power of the RF source 103 is 2500 W;

the bias power is 300 W;

the N₂ gas is 450 sccm;

the H₂ gas is 50 sccm; and

the temperature of the substrate (wafer) is about 0° C. to 80° C., preferably 20° C. In this case, the protection layers 7a and 3a prevent the interlayer insulating layers 7 and 3 from being ashed by N₂ plasma gas and H₂ plasma gas. Thus, no overhang shape is generated in the interlayer insulating layers 7 and 3.

Then, an organic separating process is carried out.

Next, referring to FIG. 8H, the hard mask 8 and the interlayer insulating layer 7 are etched by a dry etching process using the hard mask 21 as a mask.

Next, referring to FIG. 8I, the hard masks 21 and 8 and the exposed portion of the via stopper 2 are etched by a two-wave, type RIE process using C₄F₈ plasma gas, Ar plasma gas or O₂ plasma gas.

Next, referring to FIG. 8K, in the same way as in FIG. 3J, an upper wiring layer 11 made of copper is formed on the entire surface.

Finally, referring to FIG. 8L, in the same way as in FIG. 3K, the upper wiring layer 11 is etched back by a two-wave, RIE process, so that the upper wiring layer 11 is left within the groove in the interlayer insulating layer 7 and is electrically connected to the lower wiring layer 1 by the via structure in the interlayer insulating layer 3.

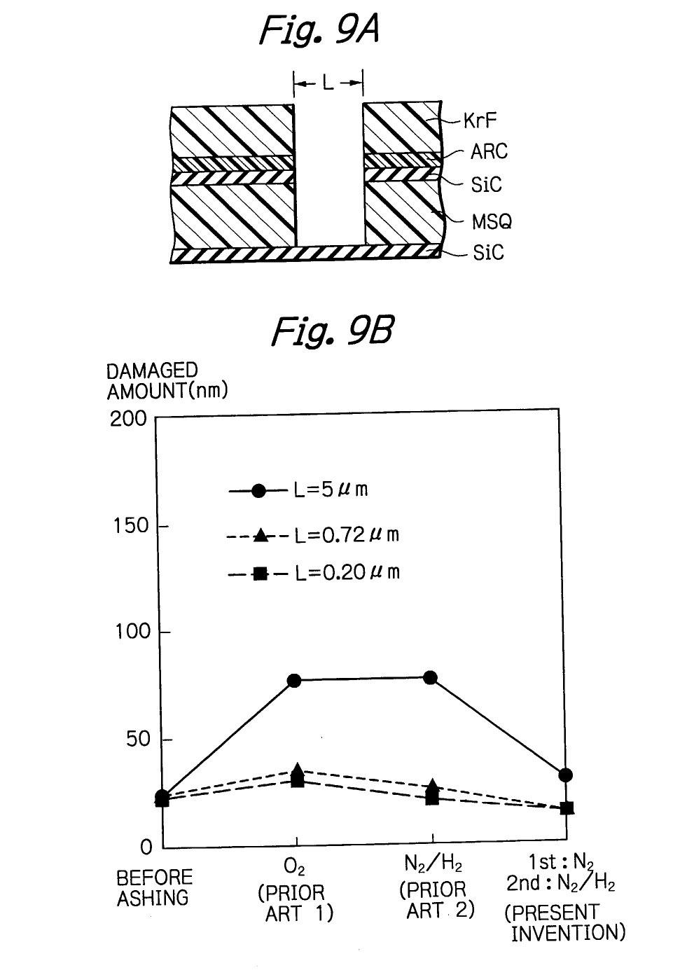

The effect of the present invention according to the inventor's experiment is explained next with reference to FIGS. 9A and 9B.

First, a sample was constructed by a groove stopper (SiC), an interlayer insulating layer (MSQ), a hard mask (SiC), an anti-reflective coating layer (ARC) and a photoresist layer (KrF). The sample as illustrated in FIG. 9A was in a state after etching of the interlayer insulating layer (MSQ) was etched and before the photoresist layer (KrF) was ashed. In this case, when the sample was put into a dilute fluoric acid, the surface of the interlayer insulating layer (MSQ) was hardly etched by the dilute fluoric acid, since the interlayer insulating layer (MSQ) included CH₃-groups. For example, the etched (damaged) amount of the interlayer insulating layer (MSQ) observed by a scanning electron microscope (SEM) was about 20 nm as illustrated in FIG. 9B.

Also, after a prior art ashing method using O₂ plasma gas or N₂/H₂ plasma gas was performed upon the sample, the sample was put into dilute fluoric acid, so that the surface of the interlayer insulating layer (MSQ) was etched by the dilute fluoric acid, since CH₃-groups were separated therefrom and the surface interlayer insulating layer (MSQ) was close to a structure of SiO₂. For example, the etched (damaged) amount of the interlayer insulating layer (MSQ) observed by the SEM was about 20 to 70 nm as illustrated in FIG. 9B.

Further, after an a two-step ashing method using N₂ plasma gas or N₂/H₂ plasma gas according to the present invention was performed upon the sample, the sample was put into dilute fluoric acid, so that the surface of the interlayer insulating layer (MSQ) was hardly etched by the dilute fluoric acid, since CH₃-groups were changed into CN-groups. For example, the etched (damaged) amount of the interlayer insulating layer (MSQ) observed by the SEM was about 10 to 25 nm as illustrated in FIG. 9B.

Thus, the above-described experiment exhibited that the surface of the interlayer insulating layer (MSQ) was hardly damaged by the two-step ashing process using N₂ plasma gas and N₂/H₂ plasma gas according to the present invention.

Note that the present invention can be applied to inorganic interlayer insulating layer including CH₃-groups or H-groups other than MSQ, HSQ and MHSQ.

Also, the stoppers 2 and 4 can be made of SiN, SiON or SiCN, and the hard mask 8 can be made of SiO₂, SiN, SiON, SiC or SiCN or their combination.

Further, an ArF photoresist layer can be used instead of the KrF photoresist layer.

As explained hereinabove, according to the present invention, since an interlayer insulating layer made of MSQ, HSQ, MHSQ or the like is hardly etched by a two-step ashing process, the generation of an overhang shape in the interlayer insulating layer can be suppressed.

1. A method for manufacturing a semiconductor device, comprising the steps of:
forming a photoresist pattern layer on an interlayer insulating layer made of inorganic material including CH₃-groups and/or H-groups;
etching said interlayer insulating layer using said photoresist pattern layer as a mask; and
performing a two-step ashing process upon said photoresist pattern layer while said interlayer insulating layer is exposed,
said two-step ashing process including a first step using N₂ plasma gas and a second step using N₂/H₂ plasma gas after said first step.

2. The method as set forth in claim 1, wherein said inorganic material comprises methyl silsesquioxane.

3. The method as set forth in claim 1, wherein said inorganic material comprises hydrogen silsesquioxane.

4. The method as set forth in claim 1, wherein said inorganic material comprises methyl hydrogen silsesquioxane.

5. The method as set forth in claim 1, wherein said two-step ashing process is performed under a state where a temperature of said interlayer insulating layer is about 0° C. to 80° C.

6. The method as set forth in claim 1, wherein said two-step ashing process is performed under a state where said N₂ plasma gas and said N₂/H₂ plasma gas have a pressure of about 1.33 to 13.3 Pa.

7. A method for manufacturing a semiconductor device, comprising the steps of:
forming a lower wiring layer;
forming a via stopper on said lower wiring layer;
forming a first interlayer insulating layer made of inorganic material including CH₃-groups and/or H-groups on said via stopper;
forming a groove stopper on said first interlayer insulating layer;
forming a first photoresist pattern layer having a via hole on said first interlayer insulating layer;
etching said groove stopper and said first interlayer insulating layer by using said first photoresist pattern layer as a mask;
performing a first two-step ashing process upon said first photoresist pattern layer, after said groove stopper and said first interlayer insulating layer are etched;
forming a second interlayer insulating layer made of inorganic material including CH₃-groups and/or H-groups on said groove stopper after said first two-step ashing process is performed;
forming a hard mask on said second interlayer insulating layer;
forming a second photoresist pattern layer having a groove hole on said second interlayer insulating layer;
etching said hard mask, said second interlayer insulating layer and said first interlayer insulating layer by using said second photoresist pattern layer as a mask;
performing a second two-step ashing process upon said second photoresist pattern layer, after said hard mask, said second interlayer insulating layer and said first interlayer insulating layer are etched;
etching said hard mask and an exposed portion said via stopper after said second two-step ashing process is performed; and
burying an upper wiring layer in a groove within said second interlayer insulating layer and in a via hole within said first interlayer insulating layer,
each of said first and second two-step ashing processes including a first step using N₂ plasma gas and a second step using N₂/H₂ plasma gas after said first step.

8. The method as set forth in claim 7, wherein said inorganic material comprises methyl silsesquioxane.

9. The method as set forth in claim 7, wherein said inorganic material comprises hydrogen silsesquioxane.

10. The method as set forth in claim 7, wherein said inorganic material comprises methyl hydrogen silsesquioxane.

11. The method as set forth in claim 7, wherein each of said first and second two-step ashing processes is performed under a state where a temperature of said interlayer insulating layer is about 0° C. to 80° C.

12. The method as set forth in claim 7, wherein each of said first and second two-step ashing processes is performed under a state where said N₂ plasma gas and said N₂/H₂ plasma gas have a pressure of about 1.33 to 13.3 Pa.

13. A method for manufacturing a semiconductor device, comprising the steps of:
forming a lower wiring layer;
forming a via stopper on said lower wiring layer;
forming a first interlayer insulating layer made of inorganic material including CH₃-groups and/or H-groups on said via stopper;
forming a groove stopper on said first interlayer insulating layer;
forming a second interlayer insulating layer made of inorganic material including CH₃-groups and/or H-groups on said groove stopper;
forming a hard mask on said second interlayer insulating layer;
forming a first photoresist pattern layer having a via hole on said hard mask;
etching said hard mask, said second interlayer insulating layer, said groove stopper and said first interlayer insulating layer by using said first photoresist pattern layer as a mask;
performing a first two-step ashing process upon said first photoresist pattern layer, after said hard mask, said second interlayer insulating layer, said groove stopper and said first interlayer insulating layer are etched;
forming a second photoresist pattern layer having a groove hole on said hard mask, after said first two-step ashing process is performed;
etching said hard mask and said second interlayer insulating layer by using said second photoresist pattern layer as a mask;
performing a second two-step ashing process upon said second photoresist pattern layer, after said hard mask and said second interlayer insulating layer are etched;
etching said hard mask and an exposed portion said via stopper after said second two-step ashing process is performed; and
burying an upper wiring layer in a groove within said second interlayer insulating layer and in a via hole within said first interlayer insulating layer,
each of said first and second two-step ashing processes including a first step using N₂ plasma gas and a second step using N₂/H₂ plasma gas after said first step.

14. The method as set forth in claim 13, wherein said inorganic material comprises methyl silsesquioxane.

15. The method as set forth in claim 13, wherein said inorganic material comprises hydrogen silsesquioxane.

16. The method as set forth in claim 13, wherein said inorganic material comprises methyl hydrogen silsesquioxane.

17. The method as set forth in claim 13, wherein each of said first and second two-step ashing processes is performed under a state where a temperature of said interlayer insulating layer is about 0° C. to 80° C.

18. The method as set forth in claim 13, wherein each of said first and second two-step ashing processes is performed under a state where said N₂ plasma gas and said N₂/H₂ plasma gas have a pressure of about 1.33 to 13.3 Pa.

19. A method for manufacturing a semiconductor device, comprising the steps of:
forming a lower wiring layer;
forming a via stopper on said lower wiring layer;
forming a first interlayer insulating layer made of inorganic material including CH₃-groups and/or H-groups on said via stopper;
forming a groove stopper on said first interlayer insulating layer;
forming a second interlayer insulating layer made of inorganic material including CH₃-groups and/or H-groups on said groove stopper;
forming a first hard mask on said second interlayer insulating layer;
forming a second hard mask on said first hard mask;
forming a first photoresist pattern layer having a groove hole on said second hard mask;
etching said second hard mask by using said first photoresist pattern layer as a mask;
performing an ashing process upon said first photoresist pattern layer, after said second hard mask is etched;
forming a second photoresist pattern layer having a via hole on said second hard mask, after said ashing process is performed;
etching said first hard mask, said second interlayer insulating layer, said groove stopper and said first interlayer insulating layer by using said second photoresist pattern layer as a mask;
performing a two-step ashing process upon said second photoresist pattern layer, after said hard mask, said second interlayer insulating layer, said groove stopper and said first interlayer insulating layer are etched;
etching said hard mask and an exposed portion said via stopper after said two-step ashing process is performed; and
burying an upper wiring layer in a groove within said second interlayer insulating layer and in a via hole within said first interlayer insulating layer,
said two-step ashing process including a first step using N₂ plasma gas and a second step using N₂/H₂ plasma gas after said first step.

20. The method as set forth in claim 19, wherein said inorganic material comprises methyl silsesquioxane.

21. The method as set forth in claim 19, wherein said inorganic material comprises hydrogen silsesquioxane.

22. The method as set forth in claim 19, wherein said inorganic material comprises methyl hydrogen silsesquioxane.

23. The method as set forth in claim 19, wherein said two-step ashing process is performed under a state where a temperature of said interlayer insulating layer is about 0° C. to 80° C.

24. The method as set forth in claim 19, wherein said two-step ashing process is performed under a state where said N₂ plasma gas and said N₂/H₂ plasma gas have a pressure of about 1.33 to 13.3 Pa.
